(19) United States
(12) Patent Application Publication
(10) Pub. No.: US 2026/0191037 A1
(43) Pub. Date: Jul. 2, 2026

(54) LOCALIZED EMBEDDED BRIDGE IN CORE

(71) Applicant: Intel Corporation, Santa Clara, CA (US)

(72) Inventors: Eng Huat GOH, Penang (MY); Jiun Hann SIR, Gelugor (MY); Seok Ling LIM, Penang (MY); Yean Ling SOON, Penang (MY); Telesphor KAMGAING, Chandler, AZ (US)

(21) Appl. No.: 19/003,408

(22) Filed: Dec. 27, 2024

(51) Int. Cl. H01L 23/538; H01L 23/00; H01L 23/15; H01L 25/18; H10B 80/00; H10D 80/30

(52) U.S. Cl. CPC H10W 70/611; H10W 70/65; H10W 90/00; H10W 90/401; H10B 80/00; H10D 80/30; H10W 70/692; H10W 90/724

(57) ABSTRACT

Embodiments disclosed herein include an apparatus that includes a package substrate, with a core. In an embodiment, a first die is on the package substrate, and the first die includes a first double data rate (DDR) physical layer and a second DDR physical layer. In an embodiment, a second die is on the package substrate, and a bridge is in a cavity of the core of the package substrate. In an embodiment, the first DDR physical layer is coupled to the second die by a first trace within the bridge, and the second DDR physical layer is coupled to the second die by a second trace within a buildup layer over the core.

### BACKGROUND

Certain semiconductor based processing systems require high memory bandwidth in order to meet product specifications. Artificial intelligence and machine learning applications are one such example of systems that need high memory bandwidth. A double data rate (DDR) physical layer (phy) is integrated into the die of the processor in order to provide an interface that is capable of communicating with the external memory at high speeds. The DDR phy is often located at an edge of the die in order to allow for simpler breakout routing solutions.

As a space savings solution, the DDR phy may be segmented and overlap each other. This reduces the shoreline dedicated to the DDR phy, which can reduce the size of the system. However, stacking the DDR phy results in the need for a more complex breakout routing solution. As such, additional layers within the underlying package substrate are needed. This increases the cost of the package substrate, and increases the time necessary to design the package substrate.

### BRIEF DESCRIPTION OF THE DRAWINGS

FIG. 1A is a plan view illustration of a die with stacked and offset double data rate (DDR) physical layers (phy) at an edge of the die, in accordance with an embodiment.

FIG. 1B is a plan view illustration of a die with stacked and aligned DDR phy at an edge of the die, in accordance with an embodiment.

FIG. 2A is a cross-sectional illustration of an electronic package with a die with stacked DDR phy that are electrically coupled to a memory device through routing in the package substrate and routing in an embedded bridge in the core of the package substrate, in accordance with an embodiment.

FIG. 2B is a cross-sectional illustration of an electronic package with a die with stacked DDR phy that are electrically coupled to a memory device through routing in an embedded bridge in the core of the package substrate, in accordance with an embodiment.

FIG. 3A is a plan view illustration of an electronic package with a die with stacked and offset DDR phy that are electrically coupled to memory devices through routing in the package substrate and routing in an embedded bridge in the core of the package substrate, in accordance with an embodiment.

FIG. 3B is a plan view illustration of an electronic package with a die with stacked and aligned DDR phy that are electrically coupled to memory devices through routing in the package substrate and routing in an embedded bridge in the core of the package substrate, in accordance with an embodiment.

FIGS. 4A-4F are cross-sectional illustrations depicting a process for forming an electronic package with a bridge embedded in a core of a package substrate to provide electrical coupling between stacked DDR phy in a first die and a second die, in accordance with an embodiment.

FIG. 5 is a flow diagram of a process for manufacturing a package substrate with a bridge embedded in a core of a package substrate to provide electrical coupling between stacked DDR phy in a first die and a second die, in accordance with an embodiment.

FIG. 6 is a schematic of a computing device built in accordance with an embodiment.

### EMBODIMENTS OF THE PRESENT DISCLOSURE

Described herein are electronic systems with dies that included stacked double data rate (DDR) physical layers (phy) that are electrically coupled to a memory device through routing in a package substrate and through routing in an embedded bridge within a core of the package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, systems that rely on high memory bandwidths (e.g., artificial intelligence systems, machine learning systems, etc.) are often physically large systems (i.e., a large footprint). One driver for the large footprint is the need to have a dedicated double data rate (DDR) physical layer (phy) along an edge of the die for easy breakout routing. Attempts have been made to segment the DDR phy and overlap at least a portion of the segments in order to decrease the shoreline of the die. For example, an x256 DDR phy module may be replaced with a pair of overlapping x128 DDR phy modules in order to achieve an equivalent to the x256 DDR phy module design.

However, the segmentation and overlapping results in the need for a more complex breakout scheme within the underlying package substrate for the electrical routing from the die to the memory device. As such, additional routing layers are needed in the package substrate. For example, eight layers in the package substrate may be needed to provide the breakout for such a stacked DDR phy arrangement. Further, since cored packages require symmetrical layer counts on either side of the core, the extra layers need to be doubled. As such, the package substrate may need to have 18 layers or more. This increases the Z-height of the package substrate, as well as increasing cost and development time.

Accordingly, embodiments disclosed herein include adding an embedded routing layer within a core of the package substrate. This allows for an outer DDR phy to be routed in the buildup layers of the package substrate and the inner DDR phy to be routed in the embedded routing layer within the core. As such, there is no need to add extra buildup layers to the package substrate. For example, there may be four or fewer buildup layers on each side of the core. This decreases package substrate Z-height, while also minimizing costs and/or development time.

In an embodiment, the embedded routing layer may be provided on a bridge or the like. For example, a silicon bridge with buildup layers for routing may be used as the embedded routing layer. The bridge with the embedded routing layer may be fabricated in a separate production line, and inserted into the core during package substrate fabrication.

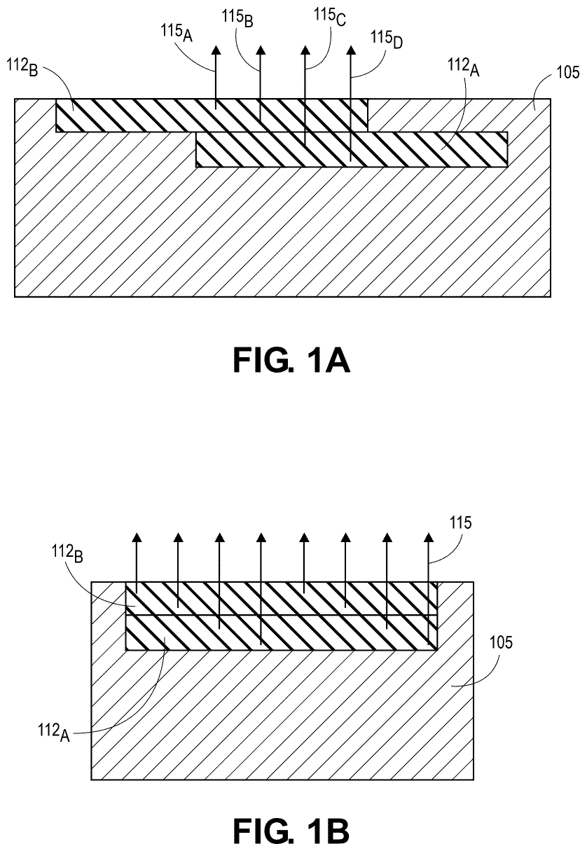

Referring now to FIG. 1A, a plan view illustration of a die 105 is shown, in accordance with an embodiment. In an embodiment, the die 105 may be a processor or the like. In an embodiment, the die 105 may include a plurality of DDR phy. For example, a first DDR phy 112_{A} and a second DDR phy 112_{B} may be provided proximate to an edge of the die 105. In an embodiment, the first DDR phy 112_{A} and the second DDR phy 112_{B} may be stacked. With respect to “stacked” DDR phy described herein, it is to be appreciated that the stacking is along a horizontal plane. That is, the first DDR phy 112_{A} is laterally adjacent to the second DDR phy 112_{B}, as opposed to being vertically stacked on top of each other. For example, the first DDR phy 112_{A} may be separated from an edge of the die 105 by the second DDR phy 112_{B}. In an embodiment, a portion of the first DDR phy 112_{A} may overlap at least a portion of the second DDR phy 112_{B} in order to reduce the necessary shoreline of the die 105. For example, in FIG. 1A an edge of the first DDR phy 112_{A} may be offset from a corresponding edge of the second DDR phy 112_{B}. An amount of the offset may be chosen based on a desired area reduction target and/or routing complexities.

In order to provide electrical routing to a memory device (not shown), a series of breakout paths in the underlying package substrate (not shown) are necessary. For example, breakout paths 115_{A}-115D are illustrated in FIG. 1A. As will be described in greater detail herein, the breakout paths 115_{A} and 115_{B} may be implemented in the buildup layers of the package substrate, and the breakout paths 115_{C} and 115_{D} may be implemented in an embedded bridge within a core of the package substrate.

Referring now to FIG. 1B, a plan view illustration of a die 105 is shown, in accordance with an additional embodiment. As shown, the first DDR phy 112_{A} and the second DDR phy 112_{B} completely overlap each other. That is, the first DDR phy 112_{A} and the second DDR phy 112_{B} may be considered as being aligned since corresponding edges of each DDR phy 112_{A} and 112_{B} are in line with each other. This may allow for a maximum space savings along a shoreline of the die 105.

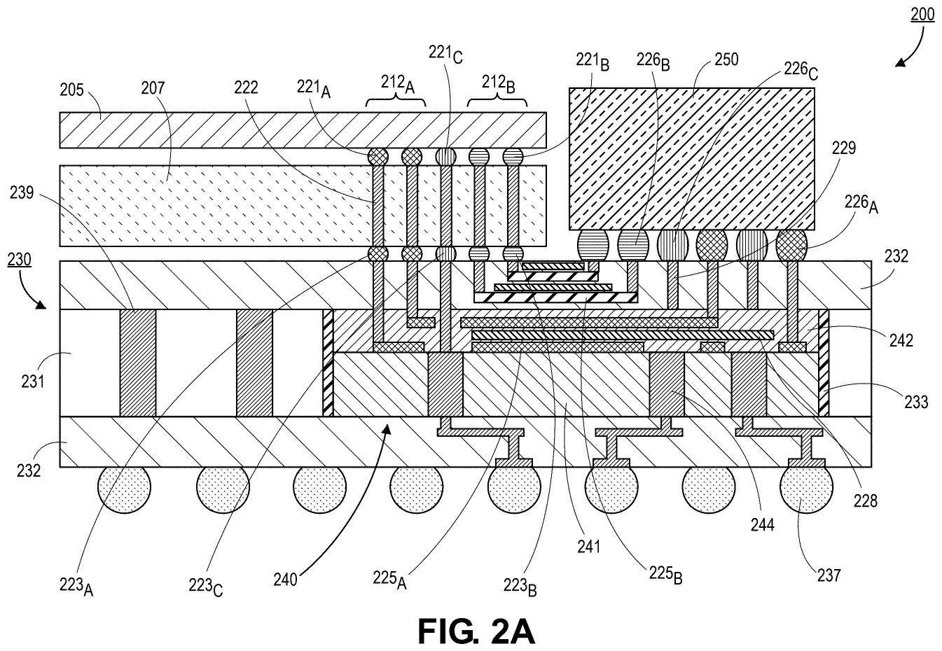

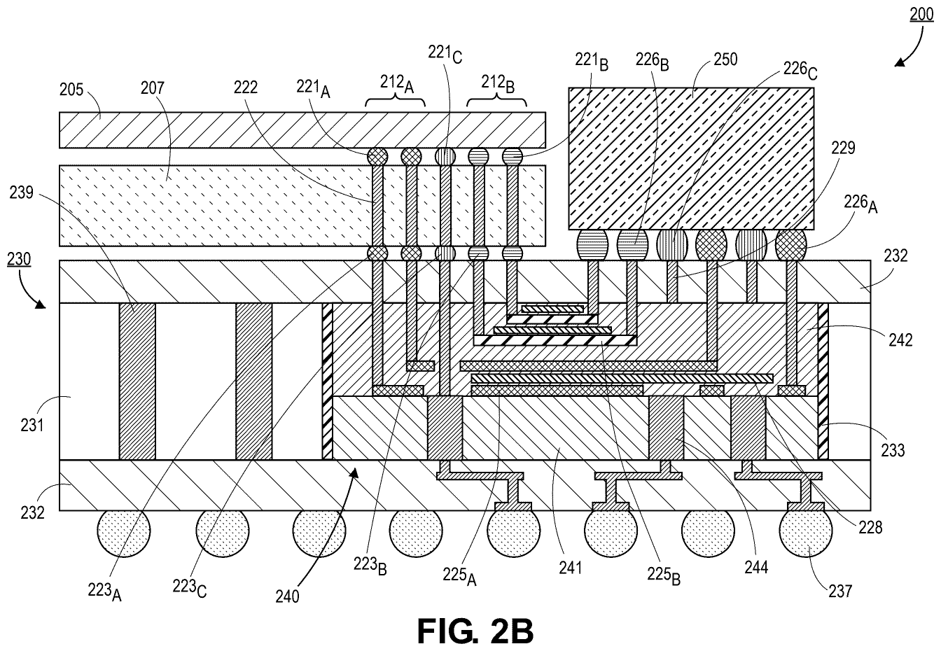

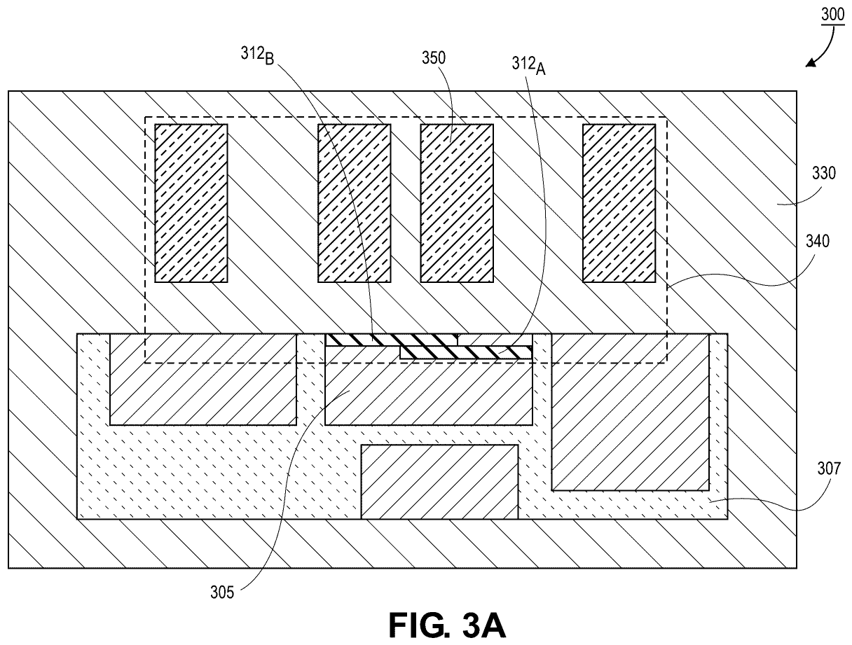

Referring now to FIG. 2A, a cross-sectional illustration of an electronic package 200 is shown, in accordance with an embodiment. As shown, the electronic package 200 may comprise a package substrate 230. The package substrate 230 may comprise a core 231 (e.g., a glass core, an organic core, or the like) and buildup layers 232 over and under the core 231. The buildup layers 232 may comprise a plurality of dielectric layers (e.g., buildup film) that are laminated over each other. In an embodiment, four or fewer laminated layers may be used to provide the DDR phy routing. A via 239 may pass through a thickness of the core 231 in some embodiments.

In an embodiment, a die 205 may be coupled to the package substrate 230 through an interposer 207. The interposer 207 may be a silicon interposer, a glass interposer or the like. In an embodiment, a plurality of dies 205 may be coupled to the interposer 207. In a particular embodiment, the die 205 is a processor. In an embodiment, a memory die 250 (or any other type of die) may also be coupled to the package substrate 230. The memory die 250 may be electrically coupled to the die 205 through traces, vias, and or the like that are embedded in the buildup layers 232 and a bridge 240 that is embedded in the core 231. In an embodiment, the die 205 may overlap a portion of the bridge 240, and the memory die 250 may overlap a portion of the bridge 240.

As shown, the die 205 comprises a first DDR phy 212_{A} and a second DDR phy 212_{B}. The second DDR phy 212_{B} may be at an edge of the die 205, and the first DDR phy 212_{A} may be spaced away from the edge of the die 205 by the second DDR phy 212_{B}. The overlapping DDR phy 212_{A} and 212_{B} may be similar to the DDR phy 112_{A} and 112_{B} described in greater detail herein. In an embodiment, first interconnects 221_{A} may electrically couple the first DDR phy 212_{A} to the interposer 207, second interconnects 221_{B} may electrically couple the second DDR phy 212_{B} to the interposer 207, and a third interconnect 221_{C} may electrically couple a power connection to the die 205. Vias 222 through the interposer 207 may electrically couple interconnects 221_{A}, 221_{B}, and 221_{C} to the interconnects 223_{A}, 223_{B}, and 223_{C}, respectively.

As shown, vias 229 through the buildup layers 232 of the package substrate 230 couple the interconnects 223_{A} to traces 225_{A} within routing layers 242 of a bridge 240 that is embedded within the core 231. The bridge 240 may include a bridge substrate 241 (e.g., glass, silicon, etc.) and routing layers 242 over the bridge substrate 241. A gap fill 233 may fill a remainder of a cavity within the core 231. A Vss line 228 may be provided between the traces 225_{A}. In an embodiment, a via 244 through the bridge substrate 241 may be electrically coupled to the interconnect 223_{C} to provide a power path through the bridge 240 to the bottom buildup layers 232 and ultimately a second level interconnect 237.

In an embodiment, the interconnects 223_{B} may be coupled to traces 225_{B} within the buildup layers 232 of the package substrate 230 by vias 229. The traces 225_{B} may be separated from each other by a Vss line 228 as well. As such, only two layers of traces 225_{B} are positioned in the buildup layers 232. This allows for a reduction in the number of buildup layers 232 of the package substrate 230. In an embodiment, vias 229 may electrically couple traces 225_{A} to interconnects 226_{A} of a memory die 250, and vias 229 may electrically couple traces 225_{B} to interconnects 226_{B} of the memory die 250. Interconnect 226_{C} may provide a power connection to the memory die 250.

Referring now to FIG. 2B, a cross-sectional illustration of a portion of an electronic package 200 is shown, in accordance with an additional embodiment. In an embodiment, the electronic package 200 in FIG. 2B may be similar to the electronic package 200 in FIG. 2A, with the exception of the electrical coupling between the second DDR phy 212_{B} and the memory die 250. Instead of providing the traces 225_{B} in the buildup layer 232 of the package substrate 230, the traces 225_{B} are embedded in the routing layer 242 of the bridge 240. That is, the electrical traces for electrically coupling both the first DDR phy 212_{A} and the second DDR phy 212_{B} may be provided in the routing layer 242 of the bridge 240. Such an embodiment may simplify the routing necessary for electrically coupling the die 205 to the memory die 250 since the routing is substantially all provided within the discrete component of the bridge 240 that can be inserted during assembly.

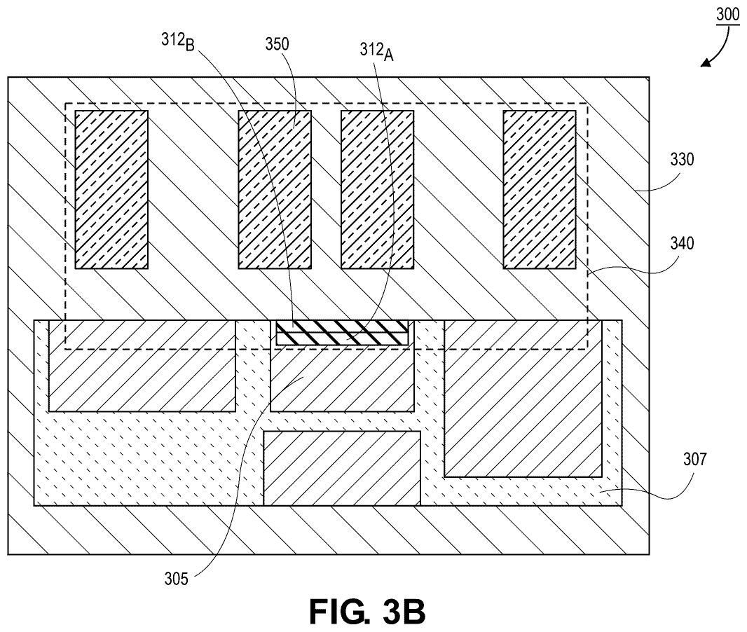

Referring now to FIG. 3A, a plan view illustration of an electronic package 300 is shown, in accordance with an embodiment. In an embodiment, the electronic package 300 may comprise a package substrate 330. The package substrate 330 may include a core (not shown). Additionally, a bridge 340 (indicated with dashed lines to indicate that it is embedded within the package substrate 330) may be provided within the core, similar to the embodiment shown in FIGS. 2A and 2B.

In an embodiment, an interposer 307 may be provided over the package substrate 330. A plurality of dies 305 may be electrically coupled to the interposer 307. In some embodiments, the interposer 307 may comprise a plurality of interconnects in order to electrically couple together two or more of the plurality of dies 305. Such a structure may sometimes be referred to as a system on a chip (SoC). As shown, at least one of the dies 305 may comprise a stacked DDR phy arrangement. For example, a first DDR phy 312_{A} may be spaced away from an edge of the die 305 by a second DDR phy 312_{B}. In an embodiment, the first DDR phy 312_{A} and the second DDR phy 312_{B} may be offset from each other so that they at least partially overlap each other. In an embodiment, a plurality of memory dies 350 may be provided over the package substrate 330 as well.

In an embodiment, the bridge 340 may provide electrical routing that electrically couples the first DDR phy 312_{A} to one or more of the memory dies 350. As shown, the bridge 340 may be within a footprint of the first DDR phy 312_{A} and one or more of the memory dies 350. The second DDR phy 312_{B} may be electrically coupled to one or more of the memory dies 350 by electrical routing within buildup layers of the package substrate 330. Though, in other embodiments, the electrical routing for electrically coupling the second DDR phy 312_{B} to one or more of the memory dies 350 may also be implemented in the bridge 340 (e.g., similar to the embodiment described with respect to FIG. 2B). The electrical coupling between the first DDR phy 312_{A} and the one or more memory dies 350, and the electrical coupling between the second DDR phy 312_{B} and the one or more memory dies 350 may be implemented similar to either of the embodiments shown in FIG. 2A or 2B.

Referring now to FIG. 3B, a plan view illustration of an electronic package 300 is shown, in accordance with an additional embodiment. The electronic package 300 in FIG. 3B may be substantially similar to the electronic package 300 in FIG. 3A, with the exception of the arrangement of the first DDR phy 312_{A} and the second DDR phy 312_{B}. Instead of being offset from each other, the first DDR phy 312_{A} and the second DDR phy 312_{B} may be aligned. Aligning the edges of the first DDR phy 312_{A} and the second DDR phy 312_{B} may allow for a further reduction in the shoreline of the die 305. As such, the footprint of the die 305, the interposer 307, and/or the package substrate 330 may be reduced compared to other embodiments.

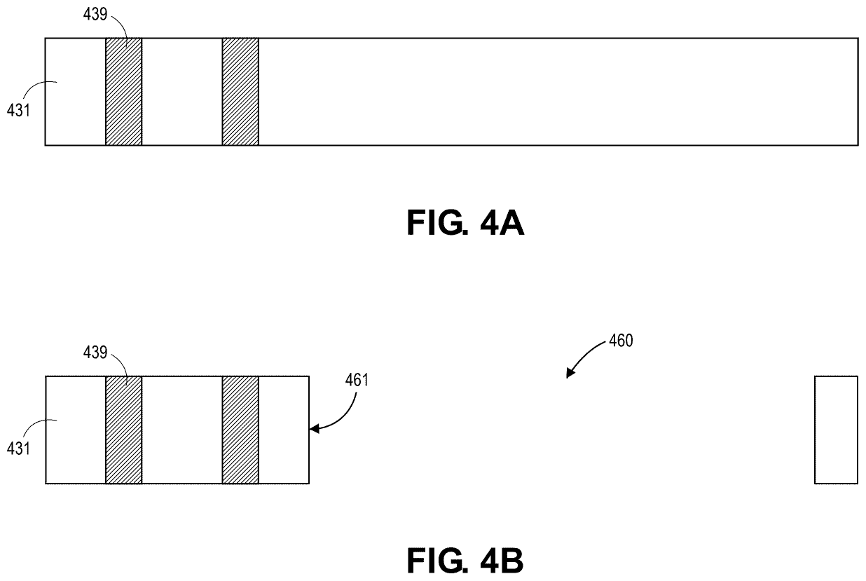

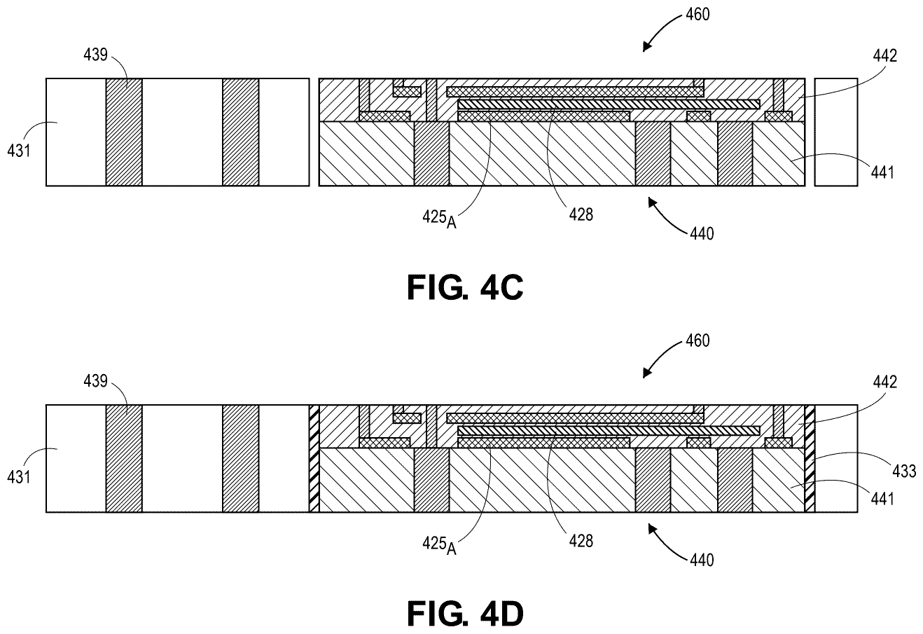

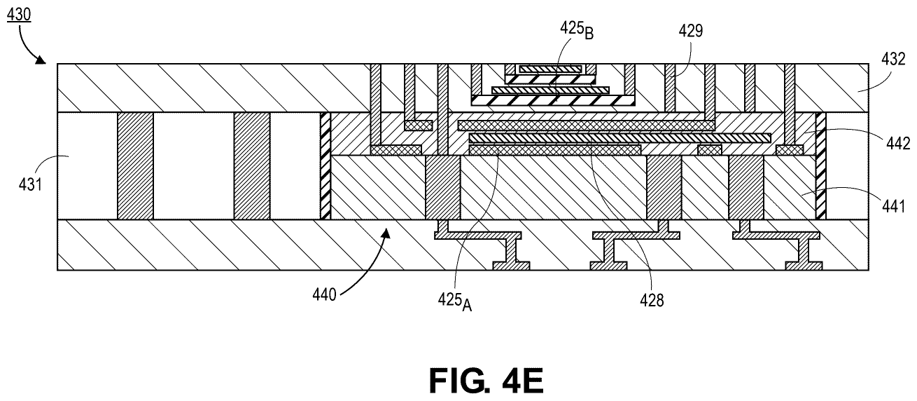

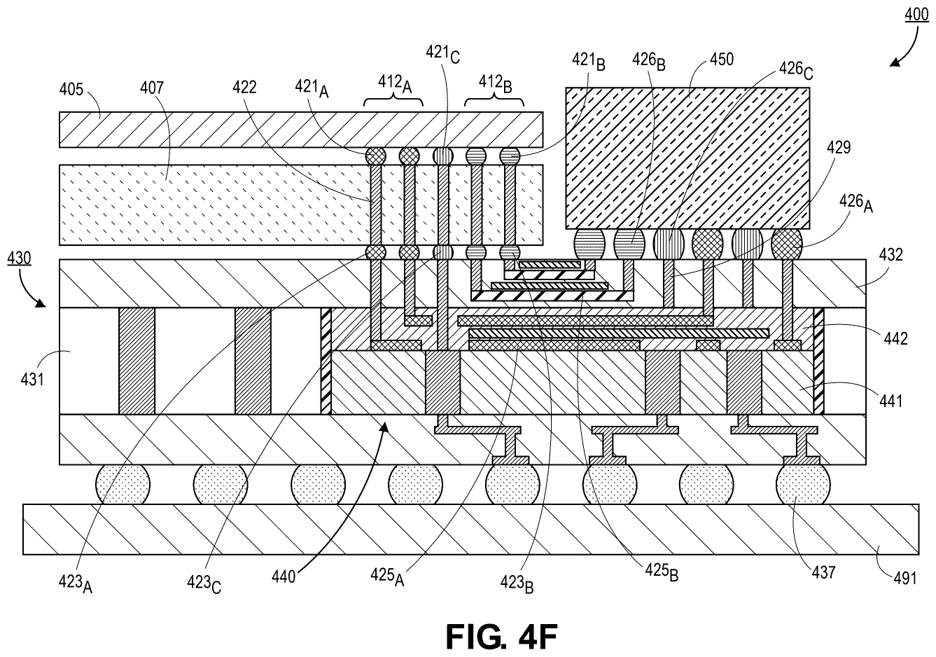

Referring now to FIGS. 4A-4F, a series of cross-sectional illustrations depicting a process for forming an electronic package with a bridge embedded in the core of a package substrate to electrically couple a stacked first DDR phy and second DDR phy to a memory die is shown, in accordance with an embodiment.

Referring now to FIG. 4A, a cross-sectional illustration of a core 431 is shown, in accordance with an embodiment. In an embodiment, the core 431 may comprise vias 439 that are formed through a thickness of the core 431. The vias 439 may be formed with any suitable process, depending on the material of the core 431.

In a particular embodiment, the core 431 comprises a glass core. In an embodiment, the glass core 431 may be substantially all glass. The glass core 431 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 431 may be distinguished from, for example, the “prepreg” or “FR4” core of a Printed Circuit Board (PCB) substrate which typically comprises glass fibers embedded in a resinous organic material, such as an epoxy.

The glass core 431 may have any suitable dimensions. In a particular embodiment, the glass core 431 may have a thickness that is approximately 50 μm or greater. For example, the thickness of the glass core 431 may be between approximately 50 μm and approximately 1.4 mm. Though, smaller or larger thicknesses may also be used. The glass core 431 may have edge dimensions (e.g., length, width, etc.) that are approximately 5 mm or greater. For example, edge dimensions may be between approximately 5 mm to approximately 250 mm. Though, larger or smaller edge dimensions may also be used. More generally, the area dimensions of the glass core 431 (from an overhead plan view) may be between approximately 10 mm×10 mm and approximately 250 mm×250 mm. In an embodiment, the glass core 431 may have a first side that is perpendicular or orthogonal to a second side. In a more general embodiment, the glass core 431 may comprise a rectangular prism volume with sections (e.g., vias) removed and filled with other materials (e.g., metal, etc.).

The glass core 431 may comprise a single monolithic layer of glass. In other embodiments, the glass core 431 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 431 may each have a thickness less than approximately 50 μm. For example, discrete layers of glass in the glass core 431 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 431 may be any suitable glass formulation that has the necessary mechanical robustness and compatibility with semiconductor packaging manufacturing and assembly processes. For example, the glass core 431 may comprise aluminosilicate glass, borosilicate glass, alumino-borosilicate glass, silica, fused silica, or the like. In some embodiments, the glass core 431 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 431 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 431 may comprise at least 23 percent silicon (by weight) and at least 26 percent oxygen (by weight). In some embodiments, the glass core 431 may further comprise at least 5 percent aluminum (by weight).

Referring now to FIG. 4B, a cross-sectional illustration of the core 431 after a cavity 460 is formed through a thickness of the core 431 is shown, in accordance with an embodiment. In an embodiment, the cavity 460 may be formed with any suitable etching process. In some embodiments, the sidewalls 461 of the cavity 460 may be substantially vertical. Other embodiments may include tapered sidewalls 461 due to the etching process. For example, in the case of a glass core 431, the cavity 460 may be formed with a laser assisted etching process or the like.

Referring now to FIG. 4C, a cross-sectional illustration of the core 431 after a bridge 440 is inserted into the core 431 is shown, in accordance with an embodiment. The bridge 440 may be similar to any of the bridges described herein. For example, the bridge 440 may comprise a bridge substrate 441 and an overlying routing layer 442. Traces 425_{A} may be embedded in different layers of the routing layer 442. In an embodiment, a Vss line 428 may also be provided between traces 425_{A}. In the illustrated embodiment, the bridge 440 has a thickness that is substantially equal to a thickness of the core 431. Though, embodiments may also include a bridge 440 with a thickness that is greater than a thickness of the core 431 or less than the thickness of the core 431.

Referring now to FIG. 4D, a cross-sectional illustration of the core 431 after a gap fill material 433 is added in order to fill remaining space within the cavity 460 is shown, in accordance with an embodiment. The gap fill material 433 may be a dielectric material, such as an epoxy, a molding material, or the like. In some embodiments, the gap fill material 433 may be omitted, and dielectric material from the overlying buildup layers (added in a subsequent operation) may fill remaining portions of the cavity 460.

Referring now to FIG. 4E, a cross-sectional illustration of the package substrate 430 after buildup layers 432 are applied over and under the core 431 is shown, in accordance with an embodiment. In an embodiment, the buildup layers 432 may comprise laminated buildup film layers or any other suitable dielectric material. Electrical routing may be provided within the buildup layers 432. For example, one or more layers of traces 425_{B} may be provided within the buildup layers 432. In an embodiment, vias 429 may also be provided within the buildup layers 432 to provide vertical electrical coupling between conductive features within the package substrate 430.

Referring now to FIG. 4F, a cross-sectional illustration of the electronic package 400 after a first die 405 and a second die 450 are electrically coupled to the package substrate 430 is shown, in accordance with an embodiment. In an embodiment, the first die 405 may be a processor with a first DDR phy 412_{A} and a second DDR phy 412_{B} provided in a stacked arrangement at an edge of the first die 405. The first die 405 may be electrically coupled to the package substrate 430 through an interposer 407. For example, interconnects 421 between the first die 405 and the interposer 407 are electrically coupled to interconnects 423 between the interposer 407 and the package substrate 430 by vias 422 through the interposer 407. The second die 450 may be a memory die that is directly coupled to the package substrate by interconnects 426.

In an embodiment, the first DDR phy 412_{A} is electrically coupled to the second die 450 through electrically conductive paths that comprise interconnects 421_{A}, vias 422, interconnects 423_{A}, vias 429 in the package substrate 430 below the first die 405, traces 425_{A} within the routing layer 442 of the bridge 440, vias 429 in the package substrate 430 below the second die 450, and interconnects 426_{A}. Similarly, the second DDR phy 412_{B} is electrically coupled to the second die 450 through electrically conductive paths that comprise interconnects 421_{B}, vias 422, interconnects 423_{B}, vias 429 in the package substrate 430 below the first die 405, traces 425_{B} within the buildup layers 432 of the package substrate 430, vias 429 in the package substrate 430 below the second die 450, and interconnects 426_{B}. Interconnects 421_{C}, 423_{C}, and 426_{C} may be used to supply power in some embodiments.

In an embodiment, the electronic package 400 may include second level interconnects 437 that are provided at a bottom of the package substrate 430. The second level interconnects 437 may electrically couple the package substrate 430 to a board 491. The board 491 may be a printed circuit board, a motherboard, or the like.

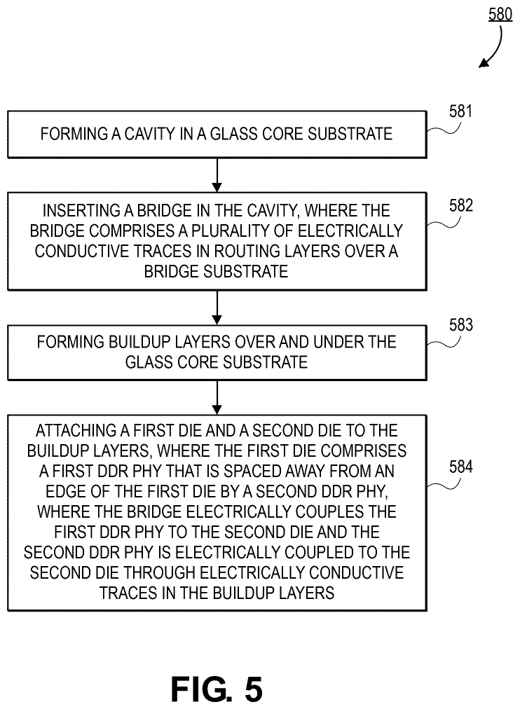

Referring now to FIG. 5, a flow diagram depicting a process 580 for assembling an electronic package with an embedded bridge for electrically coupling a first DDR phy and a second DDR phy to a memory die is shown, in accordance with an embodiment. In an embodiment, the process 580 may be similar to the process described in greater detail with respect to FIGS. 4A-4F above.

In an embodiment, the process 580 may begin with operation 581, which comprises forming a cavity in a core substrate. In an embodiment, the core may be a glass core. The cavity may be formed with any suitable process, such as a laser assisted etching process.

In an embodiment, the process 580 may continue with operation 582, which comprises inserting a bridge in the cavity. In an embodiment, the bridge comprises a plurality of electrically conductive traces in routing layers over a bridge substrate. In an embodiment, the bridge used in operation 582 may be similar to any of the bridges described in greater detail herein.

In an embodiment, the process 580 may continue with operation 583, which comprises forming buildup layers over and under the core substrate. The buildup layers may comprise laminated buildup film with associated electrically conductive features (e.g., traces, pads, vias, and/or the like). In an embodiment, four or fewer buildup layers are provided over each surface of the core substrate.

In an embodiment, the process 580 may continue with operation 584, which comprises attaching a first die and a second die to the buildup layers. In an embodiment, the first die comprises a first DDR phy that is spaced away from an edge of the first die by a second DDR phy. In an embodiment, the bridge electrically couples the first DDR phy to the second die and the second DDR phy is electrically coupled to the second die through electrically conductive traces in the buildup layers. In an embodiment, the electrically conductive traces in the bridge are part of an electrically conductive path that electrically couples the first DDR phy to the second die. In an embodiment, electrically conductive traces in the buildup layers over the core are part of an electrically conductive path that electrically couples the second DDR phy to the second die.

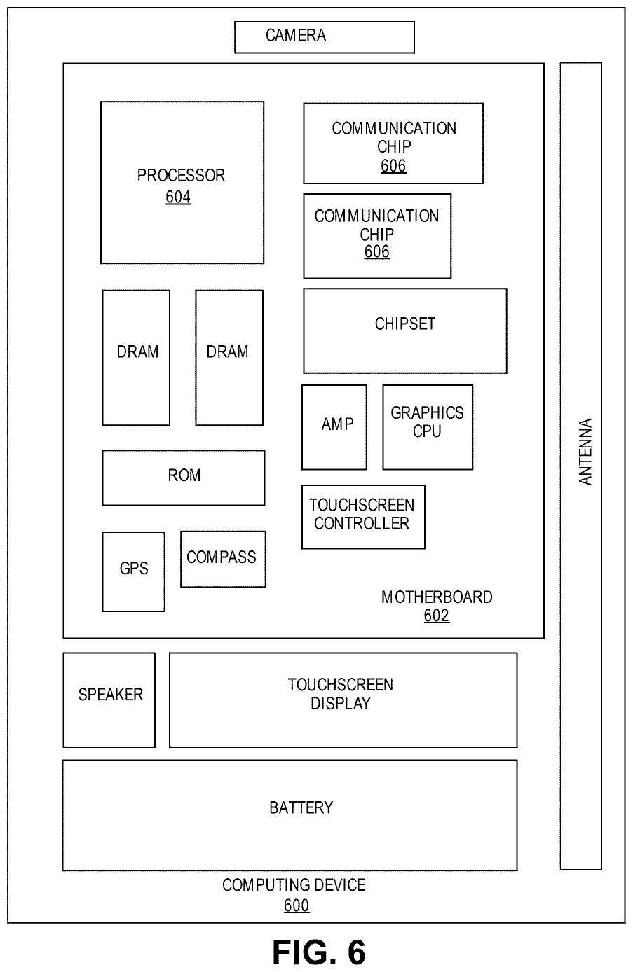

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604. In an embodiment, a device package is coupled to the board 602. One or both of the processor 604 or the communication chip 606 may be coupled to the board 602 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of a package substrate with a bridge embedded in a core of the package substrate to allow for routing stacked DDR phy from a first die to a second die, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of a package substrate with a bridge embedded in a core of the package substrate to allow for routing stacked DDR phy from a first die to a second die, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

### Example 1

an apparatus, comprising: a substrate with a cavity, wherein the substrate comprises a glass layer; a bridge in the cavity, wherein the bridge comprises a first trace; a buildup layer over the substrate and the bridge, wherein a second trace is in the buildup layer; a first die on the buildup layer, wherein the first die comprises a first double data rate (DDR) physical layer and a second DDR physical layer, and wherein the first DDR physical layer is spaced away from an edge of the first die by the second DDR physical layer; and a second die on the buildup layer, and wherein the first DDR physical layer is coupled to the second die by a first electrically conductive path that comprises the first trace and the second DDR physical layer is coupled to the second die by a second electrically conductive path that comprises the second trace.

### Example 2

the apparatus of Example 1, wherein the bridge comprises a bridge substrate and a routing layer over the bridge substrate, and wherein the first trace is embedded in the routing layer.

### Example 3

the apparatus of Example 2, further comprising a via through the bridge substrate.

### Example 4

the apparatus of Examples 1-3, wherein the first die is over a first portion of the bridge, and wherein the second die is over a second portion of the bridge.

### Example 5

the apparatus of Examples 1-4, wherein the first die is a processor, and wherein the second die is a memory die.

### Example 6

the apparatus of Examples 1-5, wherein a first edge of the first DDR physical layer is aligned with a second edge of the second DDR physical layer.

### Example 7

the apparatus of Examples 1-6, wherein the first DDR physical layer is offset from the second DDR physical layer.

### Example 8

the apparatus of Examples 1-7, further comprising: a third trace on the bridge, wherein the first trace is in a first layer of a routing layer of the bridge and the third trace is in a second layer of the routing layer of the bridge; and a fourth trace in the buildup layer, wherein the second trace is in a third layer of the buildup layer and the fourth trace is in a fourth layer of the buildup layer.

### Example 9

the apparatus of Example 8, wherein the third trace electrically couples the first DDR physical layer to the second die, and wherein the fourth trace electrically couples the second DDR physical layer to the second die.

### Example 10

the apparatus of Examples 1-9, wherein the first DDR physical layer and the second DDR physical layer are x128 DDR physical layer modules.

### Example 11

an apparatus, comprising: a package substrate, wherein the package substrate comprises a core; a first die on the package substrate, wherein the first die comprises a first double data rate (DDR) physical layer and a second DDR physical layer; a second die on the package substrate; and a bridge in a cavity of the core of the package substrate, wherein the first DDR physical layer is coupled to the second die by a first trace within the bridge, and wherein the second DDR physical layer is coupled to the second die by a second trace within a buildup layer over the core.

### Example 12

the apparatus of Example 11, wherein the second DDR physical layer is between the first DDR physical layer and an edge of the first die.

### Example 13

the apparatus of Example 11 or Example 12, wherein the first die overlaps a first portion of the bridge, and wherein the second die overlaps a second portion of the bridge.

### Example 14

the apparatus of Examples 11-13, further comprising: an interposer between the first die and the package substrate.

### Example 15

the apparatus of Examples 11-14, further comprising: a board coupled to the package substrate.

### Example 16

the apparatus of Examples 11-15, wherein the core is a glass core.

### Example 17

the apparatus of Examples 11-16, wherein the first DDR physical layer and the second DDR physical layer are x128 DDR physical layer modules.

### Example 18

an apparatus, comprising: an interposer; and a plurality of dies on the interposer, wherein the plurality of dies comprises a processor die, and wherein the processor die comprises: a first double data rate (DDR) physical layer; and a second DDR physical layer, wherein the second DDR physical layer is between the first DDR physical layer and an edge of the processor die.

### Example 19

the apparatus of Example 18, wherein the first DDR physical layer is aligned with the second DDR physical layer.

### Example 20

the apparatus of Example 18 or Example 19, wherein the first DDR physical layer is offset from the second DDR physical layer.

What is claimed is:

1. An apparatus, comprising:
a substrate with a cavity, wherein the substrate comprises a glass layer;
a bridge in the cavity, wherein the bridge comprises a first trace;
a buildup layer over the substrate and the bridge, wherein a second trace is in the buildup layer;
a first die on the buildup layer, wherein the first die comprises a first double data rate (DDR) physical layer and a second DDR physical layer, and wherein the first DDR physical layer is spaced away from an edge of the first die by the second DDR physical layer; and
a second die on the buildup layer, and wherein the first DDR physical layer is coupled to the second die by a first electrically conductive path that comprises the first trace and the second DDR physical layer is coupled to the second die by a second electrically conductive path that comprises the second trace.

2. The apparatus of claim 1, wherein the bridge comprises a bridge substrate and a routing layer over the bridge substrate, and wherein the first trace is embedded in the routing layer.

3. The apparatus of claim 2, further comprising a via through the bridge substrate.

4. The apparatus of claim 1, wherein the first die is over a first portion of the bridge, and wherein the second die is over a second portion of the bridge.

5. The apparatus of claim 1, wherein the first die is a processor, and wherein the second die is a memory die.

6. The apparatus of claim 1, wherein a first edge of the first DDR physical layer is aligned with a second edge of the second DDR physical layer.

7. The apparatus of claim 1, wherein the first DDR physical layer is offset from the second DDR physical layer.

8. The apparatus of claim 1, further comprising:
a third trace on the bridge, wherein the first trace is in a first layer of a routing layer of the bridge and the third trace is in a second layer of the routing layer of the bridge; and
a fourth trace in the buildup layer, wherein the second trace is in a third layer of the buildup layer and the fourth trace is in a fourth layer of the buildup layer.

9. The apparatus of claim 8, wherein the third trace electrically couples the first DDR physical layer to the second die, and wherein the fourth trace electrically couples the second DDR physical layer to the second die.

10. The apparatus of claim 1, wherein the first DDR physical layer and the second DDR physical layer are x128 DDR physical layer modules.

11. An apparatus, comprising:
a package substrate, wherein the package substrate comprises a core;
a first die on the package substrate, wherein the first die comprises a first double data rate (DDR) physical layer and a second DDR physical layer;
a second die on the package substrate; and
a bridge in a cavity of the core of the package substrate, wherein the first DDR physical layer is coupled to the second die by a first trace within the bridge, and wherein the second DDR physical layer is coupled to the second die by a second trace within a buildup layer over the core.

12. The apparatus of claim 11, wherein the second DDR physical layer is between the first DDR physical layer and an edge of the first die.

13. The apparatus of claim 11, wherein the first die overlaps a first portion of the bridge, and wherein the second die overlaps a second portion of the bridge.

14. The apparatus of claim 11, further comprising:
an interposer between the first die and the package substrate.

15. The apparatus of claim 11, further comprising:
a board coupled to the package substrate.

16. The apparatus of claim 11, wherein the core is a glass core.

17. The apparatus of claim 11, wherein the first DDR physical layer and the second DDR physical layer are x128 DDR physical layer modules.

18. An apparatus, comprising:
an interposer; and
a plurality of dies on the interposer, wherein the plurality of dies comprises a processor die, and wherein the processor die comprises:
a first double data rate (DDR) physical layer; and
a second DDR physical layer, wherein the second DDR physical layer is between the first DDR physical layer and an edge of the processor die.

19. The apparatus of claim 18, wherein the first DDR physical layer is aligned with the second DDR physical layer.

20. The apparatus of claim 18, wherein the first DDR physical layer is offset from the second DDR physical layer.
